(19) United States
(12) Patent Application Publication
(10) Pub. No.: US 2026/0082603 A1
(43) Pub. Date: Mar. 19, 2026

(54) NEGATIVE DIFFERENTIAL RESISTANCE DEVICE FOR VOLTAGE REGULATION

(71) Applicant: Abhishek A. Sharma, Portland, OR (US)

(72) Inventor: Abhishek A. Sharma, Portland, OR (US)

(21) Appl. No.: 18/887,218

(22) Filed: Sep. 17, 2024

(51) Int. Cl. H10D 8/70; H01L 23/522

(52) U.S. Cl. CPC H10D 8/70; H10W 20/42

(57) ABSTRACT

A negative differential resistance (NDR) device, such as Gunn diode or a tunnel diode, is included in an integrated circuit device to regulate voltage delivered to circuitry on the device, such as a logic circuit or memory circuit. The NDR device may be biased at a knee voltage to provide a stable supply voltage to the IC device. The NDR device may be implemented in a metallization layer of the integrated circuit device.

### BACKGROUND

Integrated circuit (IC) devices typically receive power through a voltage supply line. It is important for the supply voltage to remain stable, e.g., to ensure reliable operation of the IC, prevent data corruption, and/or prevent damage to the components. The supply voltage can experience instability due to external factors (e.g., power surges) or internal factors (e.g., high power draw). Voltage droop refers to a reduction in voltage that occurs when a high load is applied to the power supply, e.g., if many parts of the IC are drawing power simultaneously. Voltage droop can affect performance of the IC device, leading to slower operation, instability, or malfunction if the voltage falls below a required operating level.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A and 1B illustrate cross-sections of two example Gunn diodes device, according to some embodiments of the present disclosure.

FIGS. 2A and 2B illustrate cross-sections of two example tunnel diodes, according to some embodiments of the present disclosure.

FIG. 3 illustrates an example I-V curve for negative differential resistance (NDR) devices disclosed herein, according to some embodiments of the present disclosure.

FIG. 4 is a circuit diagram of an NDR device coupled between a logic circuit and an input voltage line, according to some embodiments of the present disclosure.

FIG. 5 is a circuit diagram of an NDR device coupled between a logic circuit, an input voltage line, and a transistor, according to some embodiments of the present disclosure.

FIGS. 6A-6C illustrate different cross sections of an IC device having an NDR device within a frontside metallization stack, according to some embodiments of the present disclosure.

FIG. 7 illustrates a cross section of an IC device having an NDR device within a backside metallization stack, according to some embodiments of the present disclosure

FIGS. 8A and 8B are top views of a wafer and dies that include one or more NDR devices in accordance with any of the embodiments disclosed herein.

FIG. 9 is a cross-sectional side view of an IC device that may include one or more NDR devices in accordance with any of the embodiments disclosed herein.

FIG. 10 is a cross-sectional side view of an IC device assembly that may include one or more NDR devices in accordance with any of the embodiments disclosed herein.

FIG. 11 is a block diagram of an example computing device that may include one or NDR devices in accordance with any of the embodiments disclosed herein.

FIG. 12 is a block diagram of an example processing device that includes one or more NDR devices in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

As described herein, a negative differential resistance (NDR) device is inserted at a voltage input to an IC device to provide voltage regulation for the IC circuit, e.g., to regulate a supply line to a logic circuit within the IC device. In some examples, the NDR device is a Gunn diode. In other examples, the NDR device is a tunnel diode.

A Gunn diode, also referred to as a transferred electron device (TED), is a two-terminal device that is characterized by a current-voltage (I-V) curve with a region of negative differential resistance, or more generally, negative impedance. The I-V curve has a lower knee at the right end of the negative differential resistance region; at higher voltages (i.e., moving rightward from the lower knee), the current moves upwards. By biasing the Gunn diode at this lower knee voltage, if the load voltage deviates from the knee voltage (e.g., in response to a surge of current draw from the logic device), the current output from the Gunn diode increases, meeting the demanded current and enabling the supply line to the logic circuit to quickly revert to the bias voltage.

In general, a diode is a two-terminal device that conducts current in one direction, referred to as the forward direction, while generally blocking current in the opposite direction, referred to as the reverse direction. In the forward direction, current enters through one terminal, which is called the anode, and leaves through the other terminal, which is called the cathode. When at least a minimum voltage, referred to as a forward voltage, is applied to the anode, this turns on the diode and current flows across the diode in the forward direction, from the anode to the cathode. Different types of materials may be used to form a diode. Many semiconductor diodes include a p-n junction, which is an interface between two types of semiconductor materials, p-type and n-type. Semiconductor diodes may include silicon, germanium, or other types of semiconductor materials.

Gunn diodes do not include a p-n junction. Instead, Gunn diodes include only n-doped material, with two highly doped regions (referred to as doped regions or n+ regions) near the terminals, and a lightly doped region (referred to as an n region, active region, or buffer region) between the highly doped region. In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with holes as the primary charge carrier is referred to as p-type, and a semiconductor material or semiconductor region with electrons as the primary charge carrier is referred to as n-type. In a Gunn diode, one of the n+ doped regions is generally larger than the other, with the current traveling through the larger n+ region, through the n region, and then though the smaller n+ region. The larger n+ region provides good ohmic contact and low contact resistance with the anode, which ensures efficient carrier injection and provides proper electric field distribution through the device.

When a voltage is applied across the lightly n-doped active region, an electric field develops across the active region. Initially, current across the device increases, but after reaching the threshold voltage, the Gunn diode operates in a negative differential resistance region in which the current decreases. By biasing the Gunn diode at the far end of the negative differential resistance region, e.g., the lower knee, following variations in current either leftward (into the negative differential resistance region) or rightward, the device tends to revert back to the bias point.

As noted above, in other embodiments, the NDR device is a tunnel diode, also referred to as an Esaki diode. A tunnel diode may have a heavily-doped p-n junction with a broken band gap, where conduction band electron states on the n-side of the junction are substantially aligned with valence band hole states on the p-side of the junction. In some implementations, a tunnel diode includes one or more thin insulator layers are between two conductive layers, forming, for example, a metal-insulator-metal (MIM) diode or metal-insulator-insulator-metal (MIIM) diode. The insulator layer(s) may enable more precise control of the device through step tunneling.

Like Gunn diodes, tunnel diodes exhibit negative differential resistance in a portion of their operating range. When a tunnel diode is forward-biased past a threshold voltage, quantum mechanical tunneling occurs. Quantum tunneling refers to probabilistic tunneling of an electron through the junction, or through one or more insulator layers, where the probabilistic tunneling is governed by quantum mechanics. The quantum tunneling effect gives rise to a region in the diode's voltage vs. current behavior, where an increase in forward voltage is accompanied by a decrease in forward current, i.e., a negative resistance region. More particularly, when the voltage increases past the threshold voltage, the electron states and empty valence band hole states on either side of the p-n junction become increasingly misaligned, and the current through the transistor drops. Beyond a second threshold voltage, the diode again begins to operate as a normal diode where electrons travel by conduction across the p-n junction, and no longer by tunneling through the p-n junction barrier.

An IC device includes various circuit elements, such as transistors, that are coupled together by metal interconnects. The circuit elements and metal interconnects may be formed in different layers. In particular, one or more layers of an IC device in which transistors and/or other IC components are implemented may be referred to as a “transistor layer,” “logic layer,” or “device layer”. Layers with conductive interconnects for providing electrical connectivity (e.g., in terms of signals and power) to the transistors and/or other devices of the transistor layer of the IC device may be referred to as a “metal layer,” “metallization layer,” or “interconnect layer”. For example, the device layer may be a front-end-of-line (FEOL) layer, while the metal layers may be back-end-of-line (BEOL) layers formed over the FEOL layer. A set of metallization layers are referred to as a metallization stack. In some embodiments disclosed herein, a first metallization stack is formed over a front side of the device layer, and a second metallization stack is formed over the back side of the IC device, i.e., on an opposite side of the device layer from the first metallization stack. The second metallization stack may be coupled to back-side contacts of the diodes and transistors.

Typically, an IC device includes a metallization stack, which is a collection of several metal layers, stacked above one another, in which different interconnects are provided. The interconnects include electrically conductive trenches, also referred to as lines, which provide connectivity across the layer, and electrically conductive vias (or, simply, “vias”) that provide electrical connectivity between different layers. In general, the term “trench” or “line” may be used to describe an electrically conductive element isolated by an insulator material (e.g., an insulator material typically comprising a low-k dielectric) that is provided in a plane parallel to the plane of an IC die/chip or a support structure over which an IC structure is provided, while the term “via” may be used to describe an electrically conductive element that interconnects two or more trenches of different levels of a metallization stack, or a component of the transistor layer and one or more trenches of a metallization layer. To that end, a via may be provided substantially perpendicularly to the plane of an IC die/chip or a support structure over which an IC structure is provided, and the via may interconnect two trenches in adjacent levels, two trenches in not adjacent levels, and/or a component of a transistor layer and a trench in adjacent or not adjacent layers. Sometimes, trenches and vias may be referred to as “metal trenches/tracks/lines/traces” and “metal vias”, respectively, to highlight the fact that these elements include electrically conductive materials such as, but not limited to, metals. Together, trenches and vias may be referred to as “interconnects,” “interconnect structures,” or “conductive structures,” where these terms may be used to describe any element formed of an electrically conductive material for providing electrical connectivity to/from one or more components associated with an IC or/and between various such components.

As disclosed herein, one or more NDR devices, such as Gunn diodes or tunnel diodes, may be included in a metallization stack of an IC device. Including an NDR device in the metallization stack, rather than on the device layer, preserves more of the semiconductor surface area for transistors or other semiconductor-based devices. The NDR devices in the metallization stack may be fabricated using existing thin-film processes. The NDR devices may be sized and shaped to fit in the metallization layers, and placed to fit between routing structures in the metal layers. The sizes and materials of the NDR devices may be selected to provide device characteristics (e.g., bias voltage) based on the voltage level(s) of the IC device, e.g., the power supply voltage of the IC device.

The NDR devices described herein may be implemented in combination with one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent.

In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g., logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

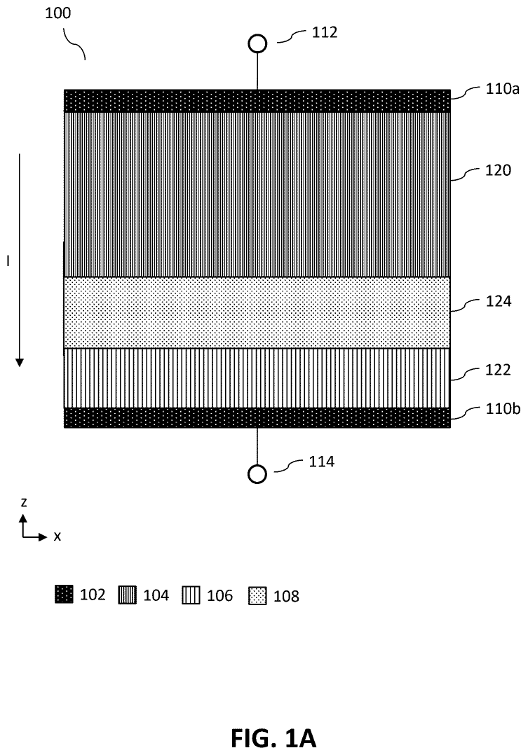

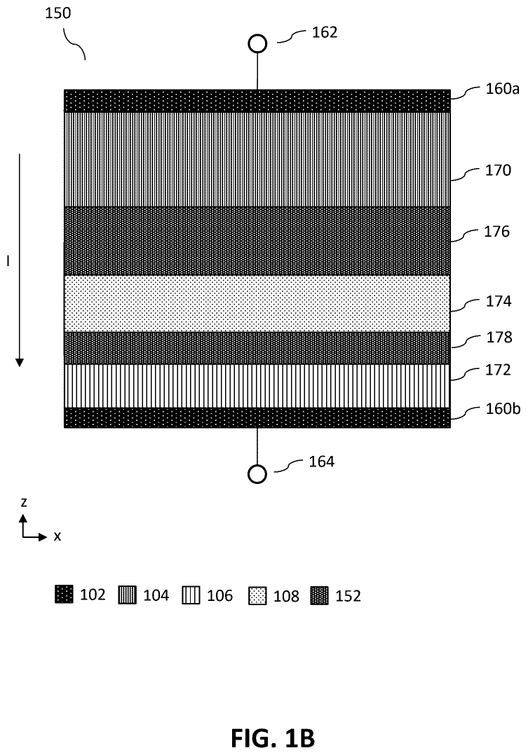

For convenience, if a collection of drawings designated with different letters are present, e.g., FIGS. 1A-1B, such a collection may be referred to herein without the letters, e.g., as “FIG. 1.”

### Example NDR Devices

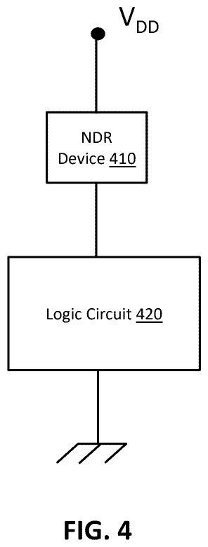

FIGS. 1A and 1B illustrate cross-sections of two example Gunn diodes 100 and 150, which are two examples of an NDR device according to some embodiments of the present disclosure. One or more Gunn diodes 100 or 150 may be included in an IC device, as shown in FIGS. 4-7, e.g., in a metallization stack of an IC device. A number of elements referred to in the description of FIGS. 1, 2, 6, and 7 with reference numerals are illustrated in these figures with different patterns, with a legend showing the correspondence between the reference numerals and patterns being provided at the bottom of the drawing pages. For example, the legend in FIG. 1 illustrates that FIG. 1 uses different patterns to show a conductor 102, a first n+ material 104, a second n+ material 106, and an active material 108.

Turning first to FIG. 1A, a Gunn diode 100, also referred to as a diode 100, is illustrated. The diode 100 includes two layers 110a and 110b of the conductor 102, a first n+ region 120 of the first n+ material 104, a second n+ region 122 of the second n+ material 106, and an active region 124 of the active material 108. The layers 110a and 110b are generally referred to as metal layers, and the layers 120-124 are generally referred to as semiconductor layers or, jointly, as a semiconductor stack. The active region 124 is between the two n+ regions 120 and 122, so the active region 124 may be referred to as a middle region or middle semiconductor region of the semiconductor stack, and the n+ regions 120 and 122 on either side of the active region 124 may be referred to as outer regions or outer semiconductor regions of the semiconductor stack. Two terminals 112 and 114 are represented on the metal layers 110a and 110b; in this case, the terminal 112 is the anode, and the terminal 114 is the cathode. The forward direction, from the anode 112 to the cathode 114, is indicated by the arrow labelled I.

The active region 124 may have a thickness or height, measured in the z-direction, on the order of 1 nanometers or 10 nanometers. For example, the active region 124 may have a thickness between 1 nanometer and 100 nanometers, between 1 nanometer and 10 nanometers, between 10 nanometers and 40 nanometers, or in another range. The thickness of the active region 124 may be based at least in part on the bandgap of the active material, e.g., a high-bandgap material may have a smaller thickness (e.g., less than 10 nanometers). Each of the n+ regions 120 and 122 may also have a thickness on the order of 10 nanometers, e.g., between 10 nanometers and 100 nanometers, between 15 nanometers and 50 nanometers, between 20 nanometers and 40 nanometers, or within some other range.

The conductor 102 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the conductor 102 may include one or more electrically conductive alloys, oxides, or carbides of one or more metals.

One or more of the materials 104, 106, and 108 may include a monocrystalline semiconductor, such as silicon or germanium. For example, the active material 108 may be formed from a silicon wafer, and the n+ materials 104 and 106 are more highly doped regions of the wafer and/or doped silicon that has been epitaxially deposited.

In some embodiments, one or more of the semiconductor materials may include a compound semiconductor with a first sub-lattice of at least one element from group Ill of the periodic table (e.g., Al, Ga, In), and a second sub-lattice of at least one element of group V of the periodic table (e.g., P, As, Sb). For some embodiments, one or more of the semiconductor materials may include a Ill-V material having a high electron mobility, such as, but not limited to InGaAs, InP, InSb, and InAs. For some such embodiments, one or more of the semiconductor materials may be a ternary Ill-V alloy, such as InGaAs, GaAsSb, InAsP, or InPSb. For some InₓGa₁₋ₓAs embodiments, the In content (x) may be between 0.6 and 0.9, and may advantageously be at least 0.7 (e.g., In_{0.7}Ga_{0.3}As). For other embodiments, one or more of the semiconductor materials may be a group IV material having a high hole mobility, such as, but not limited to Ge or a Ge-rich SiGe alloy. For some example embodiments, one or more of the semiconductor materials may have a Ge content between 0.6 and 0.9, and may be at least 0.7.

In some embodiments, the active material 108 and/or n+ materials 106 and 108 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, one or more of the semiconductor materials may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N-type amorphous or polycrystalline silicon, germanium, indium gallium arsenide, silicon germanium, gallium nitride, aluminum gallium nitride, indium phosphite, and black phosphorus.

In some embodiments, the active material 108 and/or n+ materials 106 and 108 include silicon and carbon (e.g., silicon carbide). In some embodiments, the active material 108 and/or n+ materials 106 and 108 include tungsten combined with one or more of nitrogen, selenium, and sulfur (e.g., tungsten nitride, tungsten diselenide, or tungsten disulfide), or molybdenum combined with one or more of nitrogen, selenium, and sulfur (e.g., molybdenum nitride, molybdenum diselenide, or molybdenum disulfide).

At least a portion of the n+ regions 120 and 122 may be formed using epitaxial growth. In general, epitaxial growth involves crystal growth or material deposition in which crystalline layers are grown over an existing crystal structure, where the grown layers are formed with one or more well-defined orientations with respect to the underlying crystal structure. To form Gunn diodes, the epitaxial growth process is well-controlled and produces crystal layers having a minimal amount of defects.

The materials 104, 106, and 108 of the first n+ region 120, second n+ region 122, and active region 124, respectively, are selected such that the active region 124 has a lower dopant concentration than the first n+ region 120 and second n+ region 122. The first n+ region 120, second n+ region 122, and active region 124 all have the same charge carrier, i.e., n-type charge carriers. In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with electrons as the primary charge carrier is referred to as n-type. Doping may be used to create an n-type material; for example, silicon can be doped with another element such that the resulting doped material is n-type. Suitable n-type dopants for one or more of the materials 104, 106, and 108 may include phosphorus, arsenic, antimony, phosphorous, tellurium, sulfur, tin, silicon, germanium, etc.

In general, the active material 108 may have a relatively low level of a dopant, e.g., a lower dopant concentration than the first n+ material 104 and the second n+ material 106. For example, the first n+ material 104 is a highly-doped n-type material, the active material 108 is a lower-doped n-type material, and the second n+ material 106 is a highly-doped n-type material. The active material 108 may have a dopant concentration on the order of 10¹⁶ to 10¹⁸ cm⁻³. The first n+ material 104 and second n+ material 106 may each have a dopant concentration on the order of 10¹⁸ to 10²⁴ cm⁻³. In some embodiments, the dopant concentration of the n+ materials 104 and 106 is at least ten times greater, at least 100 times greater, or at least 1000 times greater than the dopant concentration of the active material 108. In some embodiments, different dopants (e.g., different ones of the phosphorus, arsenic, antimony, etc.) may be included in different ones of the materials 104, 106, and 108. In some embodiments, the active material 108 may have the same dopant as the first n+ material 104 and/or the second n+ material 106, but at a lower concentration. Furthermore, the base material (e.g., silicon, germanium, etc.) for each of these regions may be the same or different. For example, the active material 108 may have a wider bandgap than the n+ materials 104 and 106.

In some embodiments, the n+ regions 120 and 122 have different dopant concentrations. The heights selected for the n+ regions 120 and 122 may be inversely related to the dopant concentrations of the n+ regions 120 and 122. At the anode 112, a relatively large collector has a relatively low dopant concentration, and at the cathode 114, a relatively small emitter has a relatively high dopant concentration. For example, the first n+ region 120, which is larger (as shown in FIG. 1), may have a lower dopant concentration than the second n+ region 122, which is smaller.

FIG. 1B illustrates a cross-section of a second example Gunn diode 150, according to some embodiments of the present disclosure. The diode 150 is similar to the diode 100, except that the diode 150 includes additional regions with different dopant concentrations. The diode 150 includes a first n+ region 170 and a second n+ region 172, which are similar to the n+ regions 120 and 122, respectively, of the diode 100. The diode 150 further includes a first metal layer 160a and a second metal layer 160b, which are similar to the metal layers 110a and 110b of the diode 100.

An active region 174 of the active material 108 is between the first n+ region 170 and the first n+ region 172. As noted above, the active material 108 may have a relatively low doping concentration. Unlike the diode 100, the diode 150 further includes a higher-doped material 152 in a first higher-doped region 176 over the active region 174 and in a second higher-doped region 178 under the active region 174. The first higher-doped region 176 is between the active region 174 and the first n+ region 170, and the second higher-doped region 178 is between the active region 174 and the second n+ region 172.

The higher-doped material 152 may have a dopant concentration that is greater than the active material 108 and less than the first n+ material 104 and/or the second n+ material 106. For example, the higher-doped material 152 may have a dopant concentration that is at least one order of magnitude (i.e., ten times) greater than the active material 108, and/or at least one order of magnitude (i.e., ten times) less than the first n+ material 104 and/or the second n+ material 106. In other embodiments, the higher-doped material 152 has a dopant concentration that is the same as or similar to (e.g., on the same order of magnitude of) the first n+ material 104 and/or the second n+ material 106.

The height of the first higher-doped region 176 and/or second higher-doped region 178 may be between 10% and 500% of the height of the active region 174 or any range therein, where heights are measured in the z-direction in the orientation shown. For example, the height of the first higher-doped region 176 and/or second higher-doped region 178 may be less than one times the height of the active region 174, at least the same as the height as the active region 174, or at least twice the height of the active region 174.

While a single higher-doped material 152 is illustrated in FIG. 1B, in some embodiments, the first higher-doped region 176 and second higher-doped region 178 may include different materials, e.g., different n-dopants. Furthermore, in some examples, a Gunn diode may only include a more highly doped region at one end, while the active material 108 is in direct contact with the n+ region at the other side. For example, the second higher-doped region 178 may be omitted, with the active region 174 in direct contact with the second n+ region 172.

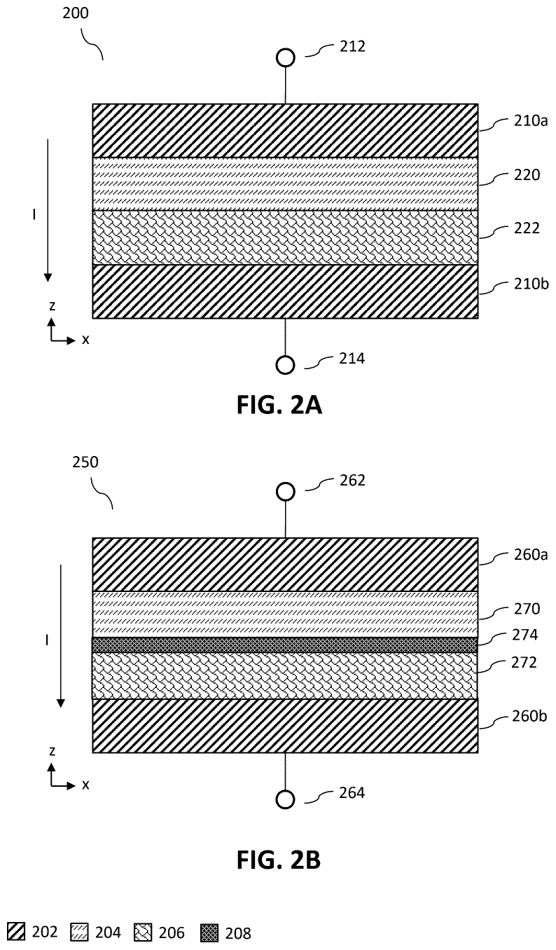

FIGS. 2A and 2B illustrate cross-sections of two example tunnel diodes, according to some embodiments of the present disclosure. One or more tunnel diodes 200 or 250 may be included in an IC device, as shown in FIGS. 4-7, e.g., in a metallization stack of an IC device. The legend in FIG. 2 illustrates that FIG. 2 uses different patterns to show the conductor 202, a first doped semiconductor 204, a second doped semiconductor 206, and an insulator 208.

Turning first to FIG. 2A, a tunneling diode 200, also referred to as a diode 200, is illustrated. The diode 200 includes two layers 210a and 210b of the conductor 202. The conductor 202 may be similar to the conductor 102, described with respect to FIG. 1. The diode 200 further includes a first doped region 220 of the first doped semiconductor 204 and a second doped region 222 of the second doped semiconductor 206 between the two layers 210a and 210b of the conductor. The layers 210a and 210b are generally referred to as metal layers, and the layers 220 and 222 are generally referred to as semiconductor layers or, jointly, as a semiconductor stack. In this example, the first doped region 220 is between the first metal layer 210a and the second doped region 222, and the second doped region 222 is between the first doped region 220 and the second metal layer 210b. Two terminals 212 and 214, an anode and a cathode, are represented on the metal layers 210a and 210b. The forward direction, from the anode 212 to the cathode 214, is indicated by the arrow labelled I.

The first doped semiconductor 204 and second doped semiconductor 206 may include monocrystalline semiconductor materials, such as silicon or germanium. The first doped semiconductor 204 and/or second doped semiconductor 206 may be a semiconductor material that is suitable for depositing as a thin film. The first doped semiconductor 204 and/or second doped semiconductor 206 may include, for example, one or more of indium, gallium, tin, zinc, antimony, arsenic, copper, nickel, niobium, titanium, and oxygen. For example, the first doped semiconductor 204 and/or second doped semiconductor 206 may include gallium and arsenic (e.g., gallium arsenide) or gallium and antimony (e.g., gallium antimonide). In some embodiments, the first doped semiconductor 204 and/or second doped semiconductor 206 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide.

Further examples include cobalt oxide, copper oxide, nickel oxide, niobium oxide, copper peroxide, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc.

The first doped semiconductor 204 and second doped semiconductor 206 may have opposite dopant types, e.g., the first doped semiconductor 204 is a p-type material and the second doped semiconductor 206 is an n-type material. Both the first doped semiconductor 204 and the second doped semiconductor 206 may be heavily doped, e.g., with a dopant concentration of 1000 impurities per 10,000,000 semiconductor atoms. The dopant concentration within the first doped semiconductor 204 and the second doped semiconductor 206 may be on the order of 10¹⁹ to 10²⁰ dopants per cubic centimeter (i.e., 10¹⁹ to 10²⁰ cm⁻³). For example, the dopant concentrations in the first doped region 220 and second doped region 222 may be greater than 10¹⁸ cm⁻³, at least 10¹⁹ cm⁻³, between 10¹⁸ cm⁻³ and 10²⁰ cm⁻³, between 10¹⁹ cm⁻³ and 10²⁰ cm⁻³, or within some other range. By contrast, dopant concentration of a standard p-n junction diode may be around 1000 times less, e.g., on the order of 10¹⁶ to 10¹⁷ cm⁻³. Each of the first doped region 220 and second doped region 222 may have a thickness measured in the z-direction of, e.g., less than 25 nanometers, less than 15 nanometers (nm), less than 10 nm, less than 5 nm, less than 1 nm, or less than 500 Angstroms (Å).

The heavy doping results in a narrow depletion region, e.g., a depletion region that has a narrower width than a typical p-n junction. The depletion region may have a thickness on the order of 100 Å, e.g., less than 500 Å, less than 200 Å, less than 150 Å, less than 100 Å, between 50 and 200 Å, between 50 and 100 Å, or in some other range. The semiconductor stack (which, as noted above, includes the first doped region 220 and second doped region 222) may have a first thickness (measured in the z-direction in the orientation shown), and a second thickness of the depletion region (also measured in the z-direction) may have a thickness that is no greater than 60%, no greater than 50%, no greater than 40%, no greater than 30%, no greater than 25%, no greater than 20%, or no greater than 10% of the first thickness of the semiconductor stack. For example, the thickness of the depletion region may be between 10% and 60%, between 10% and 40%, between 25% and 50%, or within some other range of the thickness of the semiconductor stack.

The narrow depletion region produces a relatively high electrical current under a relatively low amount of voltage. Tunneling results from a direct flow of electrons across the narrow depletion region, from the n-doped side (e.g., the second doped region 222) to the p-doped side (e.g., the first doped region 220). In a p-n junction diode, both positive and negative ions form the depletion region. Due to these ions, an in-built electric potential or electric field is present in the depletion region. This electric field provides an electric force that is opposite the direction of externally applied voltage. As the width of the depletion layer reduces, charge carriers can easily cross the junction. Rather than kinetic energy moving charge carriers across the junction, the charge carriers punch through junction, an effect referred to as tunneling.

FIG. 2B illustrates a cross-section of a second example tunnel diode 250, according to some embodiments of the present disclosure. The tunnel diode 250 is similar to the tunnel diode 200, except that the diode 250 includes an insulator layer 274 between the n-type layer and the p-type layer. The diode 250 includes a first doped region 270 of the first doped semiconductor 204 and a second doped region 272 of the second doped semiconductor 206; these regions 270 and 272 are similar to the doped regions 220 and 222, respectively, of the diode 200. The insulator layer 274 is between the two doped regions 270 and 272. The diode 250 further includes a first metal layer 260a and a second metal layer 260b, which are similar to the metal layers 210a and 210b of the diode 200.

The insulator layer 274 includes an insulator 208. The insulator 208 may include oxygen (e.g., an insulating oxide) and/or nitrogen (e.g., an insulating nitride). The insulator 208 may include a metal in combination with the oxygen or nitrogen, e.g., hafnium, titanium, tantalum, or nickel, to form an insulator. For example, the insulator 208 may include hafnium oxide, titanium oxide, tantalum oxide, nickel oxide, or silicon nitride. The insulator layer 274 may be thin enough for tunneling to occur, e.g., less than 25 nanometers, less than 15 nanometers, less than 10 nanometers, less than 5 nanometers, less than 1 nanometer, or less than 500 Å.

While a single insulator layer 274 is illustrated in FIG. 2B, in some embodiments, the tunnel diode 250 includes two or more insulator layers in an insulator stack. The overall thickness of the insulator stack may be in the ranges described above.

The illustrated tunnel diodes 200 and 250 are two-terminal devices, with an anode and a cathode. In some embodiments, a tunnel device further includes a gate coupled to a third terminal, forming a tunneling transistor. For example, a gate may be coupled to the first doped region 220 and/or second doped region 222 of the diode 200. The gate may be used to apply a voltage that alters the electric field within the depletion region.

### Example I-V Curves for NDR Devices

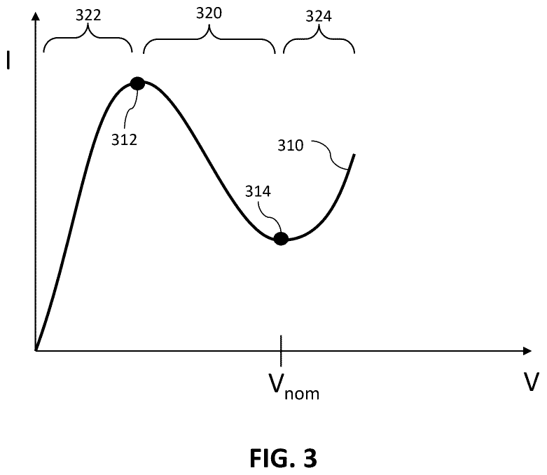

FIG. 3 illustrates an example I-V curve 310 for the NDR devices disclosed herein, such as the Gunn diodes 100 and 150 and the tunnel diodes 200 and 250. FIG. 3 illustrates voltage V along the x-axis and current I along the y-axis. In general, in an NDR device, voltage is a single valued function of the current, but the current is a multivalued function of the voltage.

The I-V curve 310 includes a negative differential resistance region 320 between the points 312 and 314; in this region 320, the current decreases as the voltage increases, and the NDR device exhibits negative resistance. The voltage at the point 312 is a threshold voltage Vₜₕ for the NDR device. When the voltage difference across an NDR device increases beyond Vₜₕ, the current density starts to decrease. The current further decreases with an increase in the applied voltage. The point 314 represents the valley voltage or valley point, at which current begins increasing again in response to increasing voltage. The region 322 is a first positive differential resistance region, and the region 324 is a second positive differential resistance region. In the regions 322 and 324, increasing voltage causes the current to increase, as typical in a p-n junction. In some implementations, an NDR device may be operated within the NDR region 320 to produce oscillations. For example, in the Gunn diode 100 and 150, sequential pulses traveling through the diode may produce a sustained oscillation at a particular oscillation frequency, where the frequency may be based on device characteristics, such as thickness of the active region and operating temperature.

Referring specifically to the tunnel diode 200 or 250, in the region 322, when a forward voltage that is less than the built-in voltage of the depletion layer is applied to the tunnel diode, a forward current does not flow through the junction, but some electrons from the conduction band of the n-doped region (e.g., the second doped region 222 or 272) tunnel to the valence band in the p-doped region (e.g., the first doped region 220 or 270). This movement creates a small forward-biased tunnel current. Thus, when a small voltage is applied to the tunnel diode 200 or 250, the tunnel current starts to flow. As the amount of voltage applied to the tunnel diode is increased, the number of free electrons generated at the n-doped side (the second doped region 222 or 272) and the number of holes at the p-doped side (the first doped region 220 or 270) is also increased, leading to increased tunnel current.

When the applied voltage increases further (e.g., past the threshold voltage point 312), there is a misalignment but still some overlap between the conduction band and the valence band, and the tunnel current decreases, resulting in the negative differential resistance of the region 320. When the applied voltage increases even further, past the valley point 314, the valence band and conduction band are completely misaligned, without any overlap; this causes the diode 200 or 250 to operate like a standard p-n junction diode within the region 324, with current increasing with voltage.

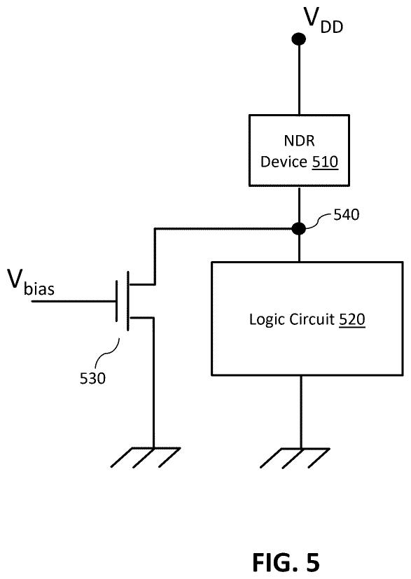

The NDR devices, including the Gunn diodes 100 and 150 and tunnel diodes 200 and 250, may be used to provide voltage regulation for the IC circuit, e.g., to regulate a supply line to a logic circuit within the IC device. For example, an NDR device may be coupled between a supply line and logic circuit as illustrated in FIG. 4 or 5. In such use cases, an NDR device may be biased at or near the voltage Vₙₒₘ, which corresponds to the voltage of the valley point 314. At the voltage Vₙₒₘ, a relatively low current passes through the NDR device. When a high load is applied to the power supply, the voltage output may drop. This condition is referred to as voltage droop, and may occur when many devices within the logic circuit are drawing power simultaneously, e.g., if many capacitors are being charged simultaneously. During the voltage droop, the NDR device moves into the negative differential resistance region 320. Specifically, moving leftward along the curve 310 from the valley point 314 causes the current passing through the NDR device to increase, and in turn, the current passing to the logic circuit to increase. This increased current can quickly satisfy the power need, enabling the voltage to return to the bias voltage Vₙₒₘ more quickly than if the NDR device is not included. A quick return to the Vₙₒₘ can enable smoother operation, e.g., greater stability and functionality of the logic circuit.

In a similar manner, if, rather than a voltage droop, there is a voltage surge (e.g., from the voltage source), the resistance across the NDR device increases in response to the increased voltage, leading to a relatively swift return (leftward along the curve 310 within the region 324) to the bias voltage Vₙₒₘ.

### Example Circuit Diagrams Implementing NDR Devices for Voltage Regulation

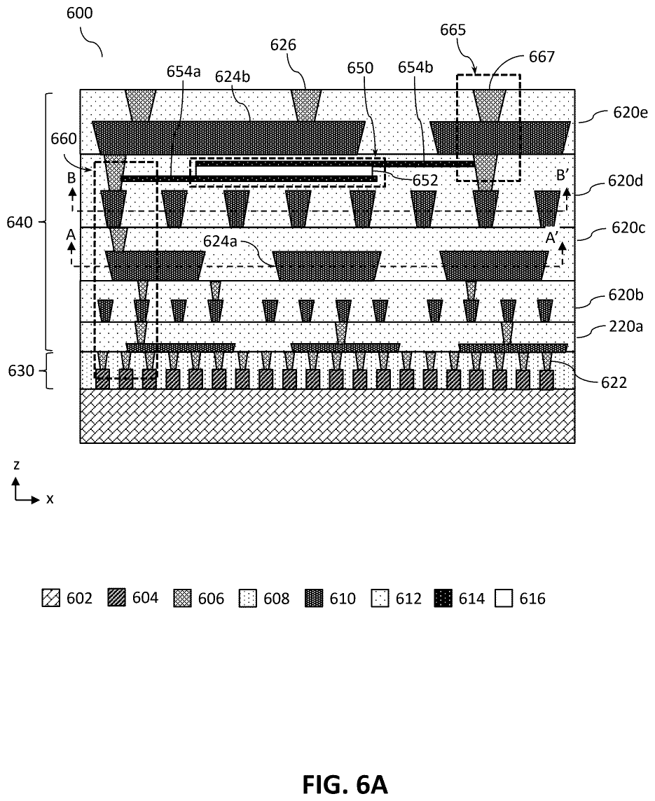

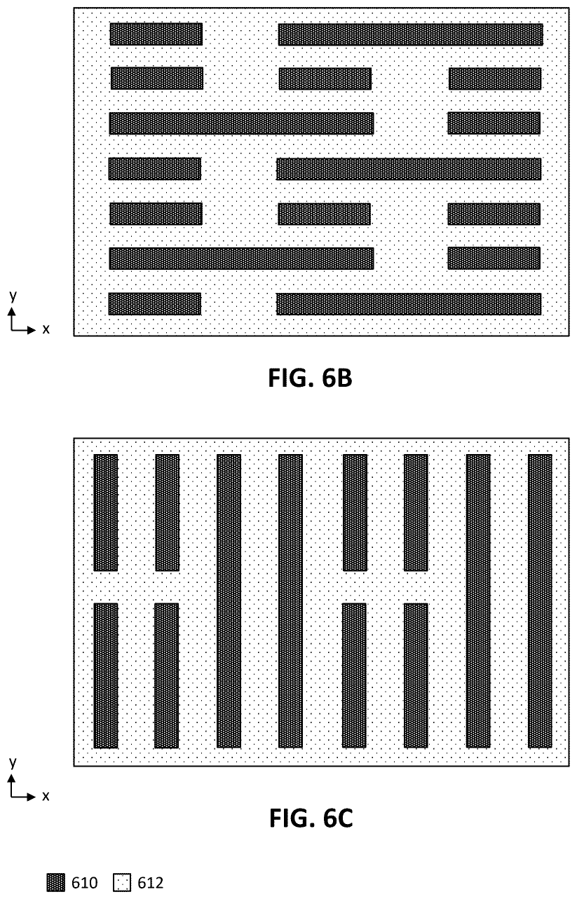

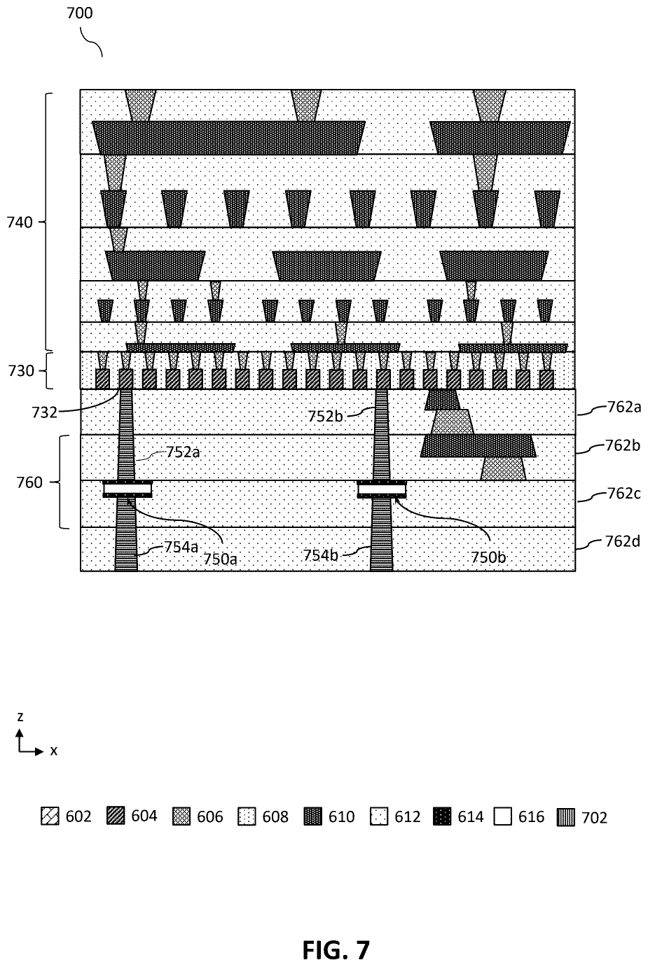

FIG. 4 is a circuit diagram of an NDR device coupled between a logic circuit and an input voltage line, according to some embodiments of the present disclosure. FIG. 4 illustrates an NDR device 410 coupled between a supply voltage V_{DD} and a logic circuit 420. The supply voltage V_{DD} may be an input voltage to an IC device, e.g., a voltage received from a circuit board to which a die including the IC device is coupled. The logic circuit 420 is further coupled to a ground (in this example, a chassis ground). The NDR device 410 may be any of the NDR devices described above, e.g., the Gunn diode 100 or 150, the tunnel diode 200 or 250, or a gated tunnel transistor. The NDR device 410 may be in a metallization stack of a die that includes the logic circuit 420, as shown in FIGS. 6 and 7. In alternate embodiments, the NDR device 410 may be formed within the logic layer of the NDR device 410, or on a separate substrate from the logic circuit 420 (e.g., on a separate die that is electrically coupled to the logic circuit 420).

One terminal of the NDR device 410, e.g., the anode, is coupled to the supply voltage V_{DD}, and an opposite terminal, e.g., the cathode, is coupled to the logic circuit 420. The NDR device 410 may be biased to the voltage Vₙₒₘ and may provide voltage regulation to the logic circuit 420. In particular, the current response of the NDR device 410 to voltage changes around the bias voltage, illustrated in FIG. 3 and discussed above, promotes return to the bias voltage in the event of voltage irregularities.

The bias voltage Vₙₒₘ is the voltage drop across the NDR device 410. The bias voltage of the NDR device 410 may be selected based on the resistance of the resistance of the logic circuit 420, referred to as R_{L}. A desired bias voltage may be achieved based on the resistance of the NDR device 410 at the valley point, referred to as R_{N} and the supply voltage V_{DD}. The bias voltage Vₙₒₘ may be calculated as follows:

$${V}_{n o m} = \frac{{R}_{N}}{{R}_{N} + {R}_{L}} {V}_{DD}$$

For example, for a supply voltage of 3V and a logic circuit load of 1 GΩ, the NDR device 410 may have a bias voltage of 1V and a resistance at the valley point of 0.5 GΩ. In this example, the supply voltage received at the logic circuit 420 (under normal conditions) is 2V, i.e., V_{DD}−Vₙₒₘ.

FIG. 5 is a circuit diagram of an NDR device coupled between a logic circuit, an input voltage line, and a transistor, according to some embodiments of the present disclosure. FIG. 5 includes an NDR device 510, which is similar to the NDR device 410, and a logic circuit 520, which is similar to the logic circuit 420. The NDR device 510 is coupled between a supply voltage V_{DD} and the logic circuit 520, and the logic circuit 520 is further coupled to a ground (in this example, a chassis ground). The NDR device 510 (e.g., the cathode of the NDR device 510) and the power input to the logic circuit 520 are coupled at a node 540. FIG. 5 further includes a bias transistor 530 having a source or drain (S/D) terminal coupled to the node 540, at the connection between the NDR device 510 and logic circuit 520. The other S/D terminal of the bias transistor 530 is coupled to a ground (in this example, the chassis ground), and the gate of the bias transistor 530 is coupled to a bias voltage, represented as V_{bias}. The NDR device 510 and bias transistor 530 may together form a voltage regulation circuit for the logic circuit 520.

As with the NDR device 410, the NDR device 510 may be in a metallization stack of a die that includes the logic circuit 520, as shown in FIGS. 6 and 7. In alternate embodiments, the NDR device 510 may be formed within the logic layer of the NDR device 510, or on a separate substrate from the logic circuit 520 (e.g., on a separate die that is electrically coupled to the logic circuit 520). The transistor 530 may be formed in the metallization stack, on the logic layer, or on a separate device with the NDR device 510 (if the logic circuit 520 is separate from the NDR device 510).

The bias transistor 530 enables the bias voltage of the NDR device 510 to be set independently from the resistance of the logic circuit 520. Thus, the voltage regulation circuit (including the NDR device 510 and bias transistor 530) may be suitable for different logic circuits 520, or if the resistance of the logic circuit 520 is not known. In this example, the bias voltage V_{bias} may be defined as follows:

$${V}_{b i a s} = \frac{{R}_{N}}{{R}_{N} + {R}_{B}} {V}_{DD}$$

where R_{N} is the resistance of the NDR device 510 at the valley point and R_{B} is the resistance of the bias transistor 530. In this example, the voltage drop across the NDR device 510 is V_{bias}/V_{DD}.
Example IC Device with NDR Device in Metallization Stack

FIGS. 6A-6C illustrate different cross sections of an IC device 600 having a device layer and multiple metal layers, according to some embodiments of the present disclosure. An NDR device described herein (e.g., the NDR devices of FIGS. 1, 2, 4, or) may be included in one or more of the metal layers, and in particular, within a frontside metallization stack of the IC device 600. FIG. 6A provides a first cross-section in an x-z plane. FIGS. 6B and 6C provide two cross-sections through the x-y plane. FIG. 6B is a cross-section through the plane AA′ in FIG. 6A, and FIG. 6C is a cross-section through the plane BB′ in FIG. 6A.

As noted above, elements referred to in the description of FIGS. 6A-6C are illustrated in these figures with different patterns, with a legend showing the correspondence between the reference numerals and patterns being provided at the bottom of the drawing pages. The legend in FIG. 6 illustrates that FIG. 6 uses different patterns to show a support structure 602, logic devices 604, a first conductive material 606, a first dielectric material 608, a second conductive material 610, a second dielectric material 612, a metal layer 614, and a semiconductor stack 616. The metal layer 614 may represent the conductor 102 or the conductor 202 of FIG. 1 or 2. The semiconductor stack 616 may represent the stacks of semiconductor materials between the metal layers in any of the diodes of FIGS. 1 and 2.

FIG. 6A illustrates cross sections of a device layer 630 and a metallization stack 640. The device layer 630 is over a support structure 602. In this example, the device layer 630 includes logic devices 604, e.g., transistors. In some embodiments, the logic devices 604, or a portion of the logic devices 604, are logic transistors in a compute logic layer or compute logic region. In some embodiments, the logic devices 604, or a portion of the logic devices, are access transistors in a memory layer, e.g., transistors that provide access to capacitor-based memory. In some embodiments, the logic devices 604 may provide transistor-based memory, such as static random-access memory (SRAM), which uses transistors arranged as latches, also referred to as flip-flops, to store data. In some embodiments, the device layer 630 and/or additional layers above or below the device layer 630 may include additional or alternative types of devices, such as capacitors, inductors, waveguides, etc.

The logic devices 604 may include a wide variety of configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors. As shown in FIG. 6A, at least a portion of the logic devices 604 may be coupled to interconnect structures in the metallization stack 640. For example, the logic devices 604 may be semiconductor devices (e.g., transistors) coupled to contacts formed from the first conductive material 606 (e.g., source, drain, and/or gate contacts). The via 622 is an example of a contact to a logic device 604.

The metallization stack 640 includes multiple metal layers 620a-620e, where 620a is the lowermost metal layer over the device layer 630, and the metal layer 620e is the uppermost metal layer. While five metal layers 620a, 620b, 620c, 620d, and 620e are illustrated in FIG. 6A, an IC device may have fewer or more metal layers, e.g., up to 10 metal layers, up to 15 metal layers, or more. In addition, while metal layers 620 are on one side (here, the front side) of the device layer 630, in other embodiments, metal layers may be included on both sides of the device layer 630, e.g., on the front side and the back side, e.g., as shown in FIG. 7.

Each metal layer 620 includes conductive structures, including metal lines or trenches (e.g., the lines 624a and 624b) formed from the second conductive material 610 and vias (e.g., the via 626) formed from the first conductive material 606. In general, interconnect structures, e.g., vias and metal lines, are referred to herein as conductive structures. While FIG. 6 illustrates a first conductive material 606 for the vias and a second conductive material 610 for the metal lines, at each metal layer, any suitable conductive material may be used. For example, in a given layer, the same conductive material may be used for both metal lines and vias. As another example, in different layers, different materials may be used for the metal lines and/or vias, e.g., ruthenium may be included in the metal lines in the metal layer 620a, while copper is included in the metal lines in the metal layer 620d. In various embodiments, conductive structures may include multiple conductive materials, e.g., a first metal as a liner, and a second metal as a fill.

The logic devices 604 are surrounded by a first dielectric material 608 in the device layer 630. The metal lines and vias in the metal layers 620a-620e are surrounded by a second dielectric material 612. In some embodiments, the dielectric materials 608 and 612 may be the same. In some embodiments, different dielectric materials may be included in different ones of the metal layers, e.g., the metal layer 620a may include a different dielectric material from the metal layer 620d. In some embodiments, multiple dielectric materials may be present in a given layer.

More generally, the dielectric materials 608 and 612 may include low-k or high-k dielectrics including, but not limited to, elements such as hafnium, silicon, oxygen, nitrogen, titanium, tantalum, lanthanum, aluminum, zirconium, barium, strontium, yttrium, lead, scandium, niobium, and zinc.

Further examples of dielectric materials include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

In addition, the conductive materials 606 and 610 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, conductive materials 606 and 610 may include one or more electrically conductive alloys, oxides, or carbides of one or more metals. The conductive materials 606 and 610 may form conductive pathways to route power, ground, and/or signals to/from various components of the logic layer 630. The arrangement of the conductive materials 606 and 610 in FIG. 6 is merely illustrative, and the conductive pathways formed by the conductive materials 606 and 610 may be connected to one another in any suitable manner.

One or more of the metal layers 620 may include one or more NDR devices. In this example, the metal layer 620d (e.g., metal layer M3) includes a diode 650, which is an example of the NDR diodes described above. The diode 650 includes a semiconductor stack 616, which may correspond to the n+ regions 120 and 122 and active region 124 of the diode 100; the n+ regions 170 and 172, the active region 174, and the higher-doped regions 176 and 178 of the diode 150; the first doped region 220 and second doped region 222 of the diode 200; or the first doped region 270, second doped region 272, and insulator layer 274 of the diode 250. The semiconductor stack 616 is between two metal plates 654a and 654b, which may correspond to the metal layers 110, 160, 210, or 260.

In some embodiments, each of the metal plates 654a and 654b extends primarily in the x-direction in the coordinate system shown, e.g., the metal plates 654a and 654b may have a longest dimension extending in the x-direction. In some cases, the metal plate of a diode may extend in perpendicular directions, e.g., one extending into the x-direction and the other into the y-direction. The diode 650, including the semiconductor stack 616, may have a rectangular or square cross-section in the x-y plane, or the cross-section through the x-y plane may have some other shape (e.g., circular, oval, triangle, etc.).

The diode 650 is a stack that includes the metal plate 654a, semiconductor stack 616, and metal plate 654b. The semiconductor stack 616 is over a portion of the metal plate 654a, and a portion of the metal plate 654b is over the semiconductor stack 616 and a portion of the metal plate 654a. The diode 650 is within the second dielectric material 612 of the metal layer 620d, with the metal plate 654a and 654b each coupled to a respective via within the metal layer 620d.

The metal plate 654a, which is the cathode, is coupled to the device layer 630, e.g., via a set of vias and trenches in the box 660. In particular, the conductive structures in the box 660 electrically couple the metal plate 654a to one or more logic devices 604, e.g., one or more transistors. The metal plate 654b, which is the anode, is coupled to a voltage supply. For example, the metal plate 654b is coupled to the set of vias and trenches in the box 665, and the uppermost via 667 in the metal layer 620e may be coupled to a voltage supply V_{DD} to the IC device 600. For illustration, the routes to the device layer 630 and ground illustrated in the boxes 660 and 665 are visible within the cross section, but in other embodiments, the routing may not be visible in a single cross-section, e.g., the route may not travel through a single x-z plane.

While the diode 650 is included in the metal layer 620d, in other examples, one or more diodes may be included in different metal layers of the IC device 600. In some embodiments, multiple diodes are included in an IC device, e.g., one or more diodes within different metal layers, and/or multiple diodes within a single metal layer.

The support structure 602 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group Ill-V materials (i.e., materials from groups Ill and V of the periodic system of elements), group II-VI (i.e., materials from groups II and IV of the periodic system of elements), or group IV materials (i.e., materials from group IV of the periodic system of elements). In some embodiments, the substrate may be non-crystalline.

Although a few examples of materials from which the support structure 602 may be formed are described here, any material that may serve as a foundation upon which an IC device as described herein may be built falls within the spirit and scope of the present disclosure.

FIGS. 6B and 6C illustrate cross-sections through two example metal layers 620c and 620d. The metal lines in a given metal layer are generally elongated structures that extend primarily in one direction within the metal layer. Typically, this direction is substantially parallel to the or perpendicular to the arrangement of the logic devices in the device layer 630, and is either perpendicular or parallel to different edges of the support structure 602, in particular, being either perpendicular or parallel to different edges of the front face or the back face of the support structure. At different metal layers 620, the metal lines may extend in different directions. For example, in the metal layer 620c, the metal lines extend in the x-direction in the coordinate system shown in FIG. 6, as illustrated in FIG. 6B. In the metal layer 620d, the metal lines extend in the y-direction in the coordinate system shown in FIG. 6 (i.e., perpendicular to the metal lines in metal layer 620c), as illustrated in FIG. 6C.

FIG. 7 illustrates a cross section of an IC device having an NDR device within a backside metallization stack, according to some embodiments of the present disclosure. While FIG. 6 included only a frontside metallization stack 640, FIG. 7 includes both a frontside metallization stack 740 and a backside metallization stack a backside metallization stack 760. The frontside metallization stack 740 is over the front side or front face of the transistor layer 730, and the backside metallization stack 760 is over a back side or back face of the transistor layer 730. The transistor layer 730 is similar to the device layer 630. The frontside metallization stack 740 is similar to the metallization stack 640, except that in this example, the frontside metallization stack 740 does not illustrate (and may not include) an NDR device, e.g., the diode 650.

In this example, the backside metallization stack 760 includes four metal layers 762a, 762b, 762c, and 762d. The metal layer 762a is the nearest metal layer to the transistor layer 730, and the metal layer 762d is the farthest metal layer from the transistor layer 730. While four metal layers 762 are illustrated in FIG. 7, an IC device may have fewer or more back side metal layers, e.g., up to 5 metal layers, up to 10 metal layers, up to 15 metal layers, or more.

The backside metallization stack 760 includes conductive structures, including metal lines or trenches formed from the conductive material 610 and vias formed from the conductive material 606.

While FIG. 7 illustrates the same conductive materials 606 and 610 for the vias and the metal lines within the backside metallization stack 760 that are included in the frontside metallization stack 740, and were included in the metallization stack 640, any suitable conductive material(s) may be used, as described with respect to the metallization stack 640. Similarly, while the metal lines and vias in the in the backside metallization stack 760 are surrounded by the first dielectric material 608, any suitable dielectric material or combination of dielectric materials may be used.

The backside metallization stack 760 further includes vias 752a, 752b, 754a, and 754b, which are formed from a conductive material 702. The conductive material 702 may include any of the conductive materials described above. The vias 752 and 754 formed from the conductive material 702 may be power delivery vias. For example, each of the vias 754a and 754b may be coupled to a power supply to the IC device 700. For example, the IC device 700 may be implemented as a die that is coupled to a circuit board, and the via 754a and/or via 754b may be coupled to a power supply line on the circuit board. The vias 752a and 752b may be coupled to the transistor layer 730 to delivery power to the transistor layer 730, e.g., to a logic circuit or memory circuit formed within the transistor layer 730.

These vias 752 and 754 may provide power delivery from the back side of the IC device, through the back side metallization stack 760.

The backside metallization stack 760 further includes NDR devices 750a and 750b, which are examples of the NDR devices described above. Each NDR device 750 is coupled between a pair of the vias 752 and 754, e.g., an upper terminal (e.g., a cathode) of the NDR device 750a is coupled to one end of the via 752a, while a lower terminal (e.g., an anode) of the NDR device 750a is coupled to one end of the via 754a. The opposite end of the via 752a is coupled to the transistor layer 730, while the opposite end of the via 754a may be coupled to a power supply, e.g., an external power source.

Each NDR device 750 includes a semiconductor stack 616, which may correspond to the n+ regions 120 and 122 and active region 124 of the diode 100; the n+ regions 170 and 172, the active region 174, and the higher-doped regions 176 and 178 of the diode 150; the first doped region 220 and second doped region 222 of the diode 200; or the first doped region 270, second doped region 272, and insulator layer 274 of the diode 250. The semiconductor stack 616 is between two metal plates, similar to the metal plates 654a and 654b, which may correspond to the metal layers 110, 160, 210, or 260. In some embodiments, the NDR device 750 may have a gate, realizing a transistor having an NDR region, such as a tunnel transistor, as described above. The NDR devices 750 may regulate voltage delivered to the logic layer 730, as described above with respect to FIGS. 4 and 5. To implement the circuit shown in FIG. 5, one or more bias transistors may be included in the backside metallization stack 760 and coupled to the NDR device(s) 750. Alternatively, a transistor in the transistor layer 730 may be the bias transistor; for example, the transistor 732, coupled to the NDR device 750a by the via 752a, may be a bias transistor.

### Example Devices

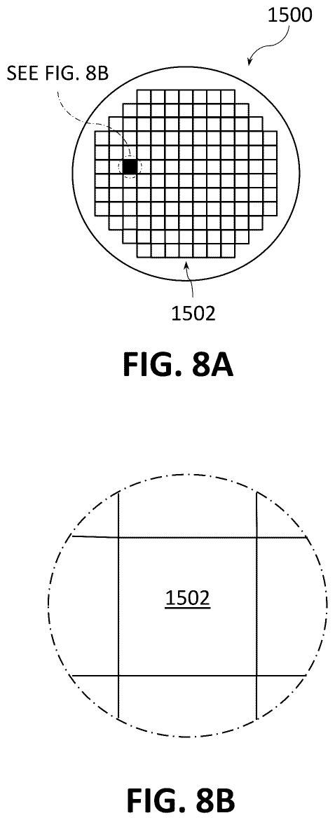

The NDR devices, and circuits including NDR devices, as disclosed herein may be included in any suitable electronic device. FIGS. 8-12 illustrate various examples of apparatuses that may include the one or more NDR devices disclosed herein, which may have been fabricated using the processes disclosed herein.

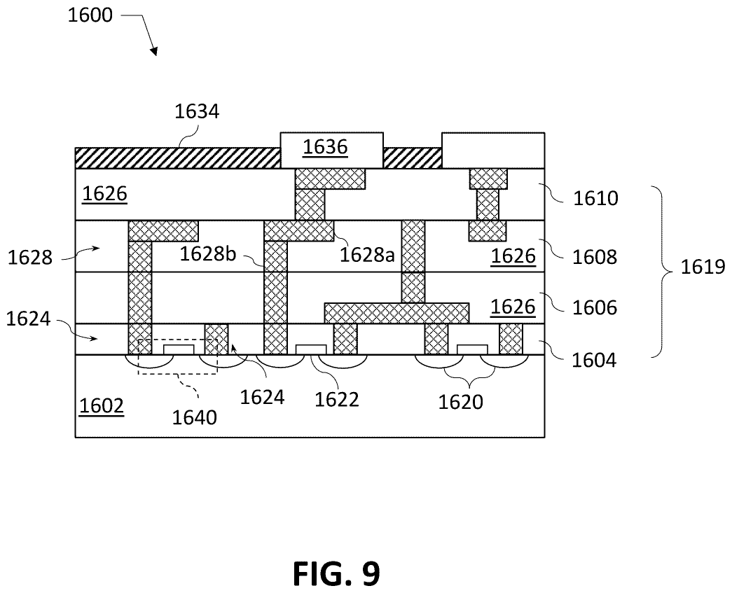

FIGS. 8A and 8B are top views of a wafer and dies that include one or more IC structures including one or more NDR devices in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1, 2, and 4-7, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 9, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element.

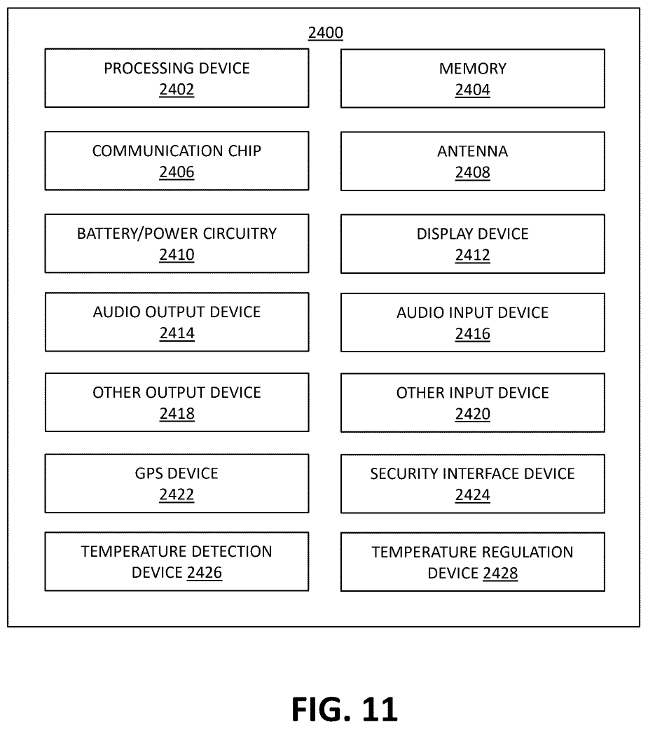

Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array.

FIG. 9 is a cross-sectional side view of an IC device 1600 that may include one or more NDR devices in accordance with any of the embodiments disclosed herein. The IC device 1600 may be formed on a substrate 1602 (e.g., the wafer 1500 of FIG. 8A) and may be included in a die (e.g., the die 1502 of FIG. 8B). The substrate 1602 may be any substrate as described herein. The substrate 1602 may be part of a singulated die (e.g., the dies 1502 of FIG. 8B) or a wafer (e.g., the wafer 1500 of FIG. 8A).

The IC device 1600 may include one or more device layers 1604 disposed on the substrate 1602.

The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more NDR devices at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group Ill-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 9 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 9). Although a particular number of interconnect layers 1606-1610 is depicted in FIG. 9, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 9. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 9. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

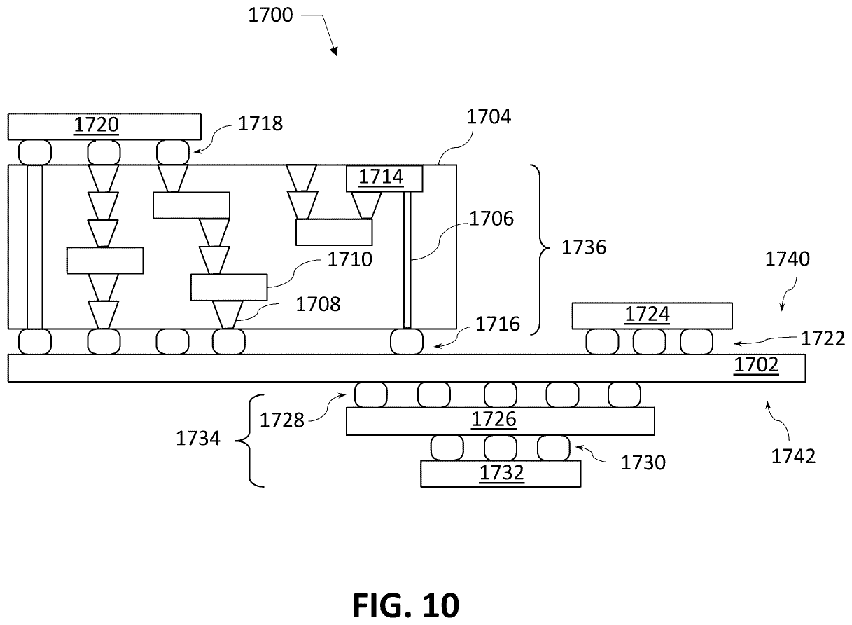

FIG. 10 is a cross-sectional side view of an IC device assembly 1700 that may include components having or being associated with (e.g., being electrically connected by means of) one or more NDR devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 10) male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 8B), an IC device (e.g., the IC device 1600 of FIG. 9), or any other suitable component. In some embodiments, the IC package 1720 may include one or more NDR devices, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 10, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group Ill-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example computing device 2400 that may include one or more components including one or more NDR devices in accordance with any of the embodiments disclosed herein. For example, any suitable ones of the components of the computing device 2400 may include a die (e.g., the die 1502 of FIG. 8) having one or more NDR devices as described herein. Any one or more of the components of the computing device 2400 may include, or be included in, an IC device 1600 of FIG. 9 or an IC device assembly 1700 of FIG. 10.

A number of components are illustrated in FIG. 11 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 11, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404).

Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off.

In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature.

Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

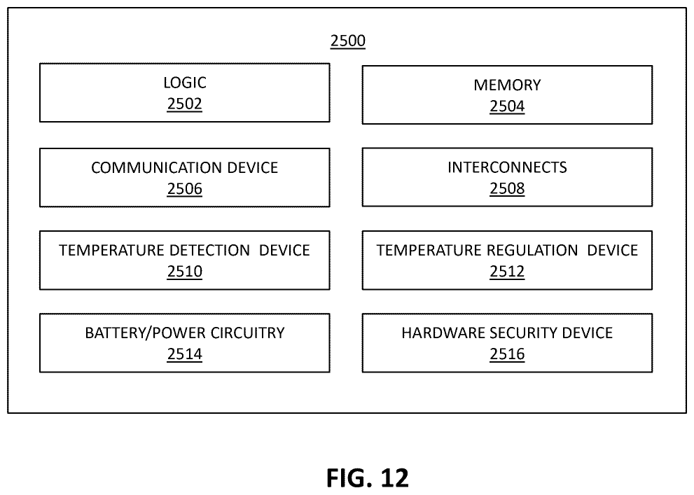

FIG. 12 is a block diagram of an example processing device 2500 that may include one or more IC devices with one or more NDR devices in accordance with any of the embodiments disclosed herein. For example, any suitable ones of the components of the processing device 2500 may include a die (e.g., the die 1502 of FIG. 8) having one or more NDR devices as described herein. Any one or more of the components of the processing device 2500 may include, or be included in, an IC device assembly 1700 (FIG. 9). Any one or more of the components of the processing device 2500 may include, or be included in, an IC device 1600 of FIG. 9 or an IC device assembly 1700 of FIG. 10. Any one or more of the components of the processing device 2500 may include, or be included in, a computing device 2400 of FIG. 11; for example, the processing device 2500 may be the processing device 2402 of the computing device 2400.

A number of components are illustrated in FIG. 12 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 12, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement 1/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides 1/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 11). In some embodiments, the memory 2504 may be a designated device configured to provide storage functionality for the components of the processing device 2500 (i.e., local), while the memory 2404 may be configured to provide system-level storage functionality for the entire computing device 2400 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 11).

In some embodiments, the communication device 2506 may be a designated device configured to provide communication functionality for the components of the processing device 2500 (i.e., local), while the communication chip 2406 may be configured to provide system-level communication functionality for the entire computing device 2400 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 of FIG. 11 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 of FIG. 11 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 of FIG. 11. In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 of FIG. 11. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The above description of illustrated implementations of the disclosure, including what is described in the Abstract, is not intended to be exhaustive or to limit the disclosure to the precise forms disclosed. Unless specified otherwise, in various embodiments, features described with respect to one of the drawings may be combined with those described with respect to other drawings.

### Select Examples

The following paragraphs provide various examples of the embodiments disclosed herein.

Example 1 provides an integrated circuit (IC) device including a logic layer including a plurality of transistors; and a metallization stack, the metallization stack including a via coupled (e.g., conductively coupled, e.g., directly electrically connected) to the logic layer; and a device coupled (e.g., conductively coupled, e.g., directly electrically connected) to the via, the device including a first n-type region having a first dopant concentration; a second n-type region having a second dopant concentration; and a third n-type region having a third dopant concentration, the third n-type region between the first n-type region and the second n-type region, and the third dopant concentration less than the first dopant concentration and less than the second dopant concentration.

Example 2 provides the IC device of example 1, where the first dopant concentration is within an order of magnitude of the second dopant concentration.

Example 3 provides the IC device of example 1 or 2, where the third dopant concentration is at least ten times less than the first dopant concentration.

Example 4 provides the IC device of example 1 or 2, where the third dopant concentration is at least 100 times less than the first dopant concentration.

Example 5 provides the IC device of any preceding example, where the first n-type region has a first height, the second n-type region has a second height, and the first height is greater than the second height.

Example 6 provides the IC device of any preceding example, further including a fourth n-type region having a fourth dopant concentration, the fourth n-type region between the first n-type region and the third n-type region, the fourth dopant concentration less than the first dopant concentration and greater than the third dopant concentration.

Example 7 provides the IC device of example 6, further including a fifth n-type region having a fifth dopant concentration, the fifth n-type region between the second n-type region and the third n-type region, the fifth dopant concentration less than the second dopant concentration and greater than the third dopant concentration.

Example 8 provides the IC device of any preceding example, where the device is a two-terminal device.

Example 9 provides the IC device of example 8, where the device is a Gunn diode.

Example 10 provides the IC device of example 9 or 10, where the via is a first via, the first n-type region is coupled (e.g., conductively coupled, e.g., directly electrically connected) to the first via, the second n-type region is coupled (e.g., conductively coupled, e.g., directly electrically connected) to a second via, and the second via is coupled (e.g., conductively coupled, e.g., directly electrically connected) to a power input of the IC device.

Example 11 provides a circuit including a transistor; and a diode including a first terminal coupled (e.g., conductively coupled, e.g., directly electrically connected) to a source or drain of the transistor; a second terminal configured for coupling to an input voltage (e.g., configured to electrically connect to an input, for example, through a pad or other electrical connector electrically connected to the second terminal); and a stack of n-type semiconductor layers between the first terminal and the second terminal, where a middle semiconductor layer of the stack has a lower dopant concentration than an outer semiconductor layer of the stack.

Example 12 provides the circuit of example 11, where the first terminal of the diode is further coupled (e.g., conductively coupled, e.g., directly electrically connected) to a logic circuit.

Example 13 provides the circuit of example 11 or 12, where the transistor includes a gate coupled (e.g., conductively coupled, e.g., directly electrically connected) to a second input voltage.

Example 14 provides the circuit of any of examples 11-13, where the first terminal of the diode is coupled to a first source or drain of the transistor, and a second source or drain of the transistor is coupled to a ground.

Example 15 provides the circuit of any of examples 11-14, where the transistor has a resistance R_{S}, the diode has a resistance R_{N}, and, for a given input voltage V_{DD}, the diode has a knee voltage of V_{DD}*R_{N}/(R_{N}+R_{S}).

Example 16 provides the circuit of any of examples 11-15, where the diode is a metallization stack of an integrated circuit (IC) device.

Example 17 provides the circuit of example 16, where the metallization stack is a backside metallization stack.

Example 18 provides an assembly including a circuit board having a voltage line; and a die coupled (e.g., conductively coupled, e.g., directly electrically connected) to the circuit board, the die including a device layer including a plurality of transistors; and a metallization stack over the device layer, the metallization stack including a via coupled (e.g., conductively coupled, e.g., directly electrically connected) to the voltage line of the circuit board; and a negative differential resistance (NDR) device coupled (e.g., conductively coupled, e.g., directly electrically connected) to the via, the NDR device including a stack of doped semiconductor materials.

Example 19 provides the assembly of example 18, where the via is a first via coupled (e.g., conductively coupled, e.g., directly electrically connected) to a first terminal of the NDR device, the metallization stack further including a second via coupled (e.g., conductively coupled, e.g., directly electrically connected) between the device layer and a second terminal of the NDR device.

Example 20 provides the assembly of example 18 or 19, where the stack of doped semiconductor materials includes an n-type layer having a first dopant concentration greater than 10¹⁸ cm⁻³; and a p-type layer having a second dopant concentration greater than 10¹⁸ cm⁻³.

Example 21 provides the assembly of example 20, further including an insulator layer between the n-type layer and the p-type layer.

Example 22 provides the assembly of example 18 or 19, where the stack of doped semiconductor materials includes a first n-type region having a first dopant concentration; a second n-type region having a second dopant concentration; and a third n-type region having a third dopant concentration, the third n-type region between the first n-type region and the second n-type region, and the third dopant concentration less than the first dopant concentration and less than the second dopant concentration.

Example 23 provides the assembly of example 22, where the third dopant concentration is at least 100 less than the first dopant concentration, and the third dopant concentration is at least 100 times less than the second dopant concentration.

Example 24 provides an integrated circuit (IC) device including a logic layer including a plurality of transistors; and a metallization stack over the logic layer, the metallization stack including a via coupled (e.g., conductively coupled, e.g., directly electrically connected) to the logic layer; and a device coupled (e.g., conductively coupled, e.g., directly electrically connected) to the via, the device including an n-type layer having a first dopant concentration greater than 10¹⁸ cm⁻³; and a p-type layer having a second dopant concentration greater than 10¹⁸ cm⁻³.

Example 25 provides the IC device of example 24, further including an insulator layer between the n-type layer and the p-type layer.

Example 26 provides the IC device of example 25, where the insulator layer has a thickness of less than 5 nanometers.

Example 27 provides the IC device of example 24, the device including a depletion region at the junction of the n-type layer and the p-type layer, the depletion region having a thickness no greater than 50% of a thickness of a semiconductor stack that includes the n-type layer and the p-type layer.

Example 28 provides the IC device of any of examples 24-27, where the n-type layer and the p-type layer each have a thickness of less than 10 nanometers.

Example 29 provides the IC device of any of examples 24-28, where the device is a two-terminal device.

Example 30 provides the IC device of any of examples 24-28, where the device further includes a gate, and the device is a three-terminal device.

Example 31 provides the IC device of any of examples 24-30, where the via is a first via, the n-type layer is coupled (e.g., conductively coupled, e.g., directly electrically connected) to the first via, the p-type layer is coupled (e.g., conductively coupled, e.g., directly electrically connected) to a second via, and the second via is coupled (e.g., conductively coupled, e.g., directly electrically connected) to a power input of the IC device.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. An integrated circuit (IC) device comprising:
a logic layer comprising a plurality of transistors; and
a metallization stack, the metallization stack comprising:
a via coupled to the logic layer; and
a device coupled to the via, the device comprising:
a first n-type region having a first dopant concentration;
a second n-type region having a second dopant concentration; and
a third n-type region having a third dopant concentration, the third n-type region between the first n-type region and the second n-type region, and the third dopant concentration less than the first dopant concentration and less than the second dopant concentration.

2. The IC device of claim 1, wherein the first dopant concentration is within an order of magnitude of the second dopant concentration.

3. The IC device of claim 1, wherein the third dopant concentration is at least ten times less than the first dopant concentration.

4. The IC device of claim 1, wherein the third dopant concentration is at least 100 times less than the first dopant concentration.

5. The IC device of claim 1, wherein the first n-type region has a first height, the second n-type region has a second height, and the first height is greater than the second height.

6. The IC device of claim 1, further comprising a fourth n-type region having a fourth dopant concentration, the fourth n-type region between the first n-type region and the third n-type region, the fourth dopant concentration less than the first dopant concentration and greater than the third dopant concentration.

7. The IC device of claim 6, further comprising a fifth n-type region having a fifth dopant concentration, the fifth n-type region between the second n-type region and the third n-type region, the fifth dopant concentration less than the second dopant concentration and greater than the third dopant concentration.

8. The IC device of claim 1, wherein the device is a two-terminal device.

9. The IC device of claim 8, wherein the device is a Gunn diode.

10. The IC device of claim 9, wherein the via is a first via, the first n-type region is coupled to the first via, the second n-type region is coupled to a second via, and the second via is coupled to a power input of the IC device.

11. A circuit comprising:
a transistor; and
a diode comprising:
a first terminal coupled to a source or drain of the transistor;
a second terminal configured for coupling to an input voltage; and
a stack of n-type semiconductor layers between the first terminal and the second terminal, wherein a middle semiconductor layer of the stack has a lower dopant concentration than an outer semiconductor layer of the stack.

12. The circuit of claim 11, wherein the first terminal of the diode is further coupled to a logic circuit.

13. The circuit of claim 11, wherein the transistor comprises a gate coupled to a second input voltage.

14. The circuit of claim 11, wherein the first terminal of the diode is coupled to a first source or drain of the transistor, and a second source or drain of the transistor is coupled to a ground.

15. The circuit of claim 11, wherein the diode is a metallization stack of an integrated circuit (IC) device.

16. The circuit of claim 15, wherein the metallization stack is a backside metallization stack.

17. An assembly comprising:
a circuit board having a voltage line; and
a die coupled to the circuit board, the die comprising:
a device layer comprising a plurality of transistors; and
a metallization stack over the device layer, the metallization stack comprising:
a via coupled to the voltage line of the circuit board; and
a negative differential resistance (NDR) device coupled to the via, the NDR device comprising a stack of doped semiconductor materials.

18. The assembly of claim 17, wherein the via is a first via coupled to a first terminal of the NDR device, the metallization stack further comprising a second via coupled between the device layer and a second terminal of the NDR device.

19. The assembly of claim 17, wherein the stack of doped semiconductor materials comprises:
an n-type layer having a first dopant concentration greater than 10¹⁸ cm⁻³; and
a p-type layer having a second dopant concentration greater than 10¹⁸ cm⁻³.

20. The assembly of claim 17, wherein the stack of doped semiconductor materials comprises:
a first n-type region having a first dopant concentration;
a second n-type region having a second dopant concentration; and
a third n-type region having a third dopant concentration, the third n-type region between the first n-type region and the second n-type region, and the third dopant concentration less than the first dopant concentration and less than the second dopant concentration.
